(19) United States
(12) Patent Application Publication
(10) Pub. No.: US 2026/0362960 A1
(43) Pub. Date: Nov. 12, 2026

(54) ORGANIC EL DEVICE CHARACTERIZATION METHOD

(71) Applicant: TOYO Corporation, Tokyo (JP)

(72) Inventors: Noriaki OYABU, Tokyo (JP); Masaru INOUE, Tokyo (JP); Hideyuki MURATA, Ishikawa (JP); Takuro IWATA, Ishikawa (JP)

(21) Appl. No.: 19/127,967

(22) PCT Filed: Nov. 10, 2023
(86) PCT No.: PCT/JP2023/040625

§ 371 Date: May 7, 2025

(30) Foreign Application Priority Data
Nov. 16, 2022 (JP) 2022-183477

(51) Int. Cl. H10K 71/70; H10K 50/155

(52) U.S. Cl. CPC H10K 71/70; H10K 50/155

(57) ABSTRACT

An organic EL device includes: a pair of electrodes; a light-emitting layer between the electrodes; a carrier transport layer (hole transport layer) between one of the electrodes and the light-emitting layer. The carrier transport layer (hole transport layer) includes an ion (cation) derived from a material different from a constituent material included in the carrier transport layer (hole transport layer), where the ion has a polarity same as the polarity of a carrier (hole) to be transported in the carrier transport layer (hole transport layer).

### TECHNICAL FIELD

The present disclosure relates to an organic electro-luminescence (EL) device, an organic EL device manufacturing method, and an organic EL device characterization method.

### BACKGROUND ART

Patent Literature (PTL) 1 discloses an optical input type organic EL element. This organic EL element has a multilayered structure with a light-emitting display part including a light-emitting layer and a carrier injection layer, and an optical response part, layered between a pair of electrodes. This organic EL element provides light-emitting display according to information that is input to the optical response part.

### CITATION LIST

### Patent Literature

[PTL 1] Japanese Unexamined Patent Application Publication No. H07-175420

### SUMMARY OF INVENTION

### Technical Problem

The present disclosure provides an organic EL device, an organic EL device manufacturing method, and an organic EL device characterization method that facilitate the improvement of characteristics including luminous efficiency.

### Solution to Problem

To achieve an object described above, an organic EL device according to one aspect of the present disclosure includes: a pair of electrodes; a light-emitting layer between the electrodes; and a carrier transport layer between one of the electrodes and the light-emitting layer. The carrier transport layer includes an ion derived from a material different from a constituent material included in the carrier transport layer, where the ion has a polarity same as the polarity of a carrier to be transported in the carrier transport layer.

To achieve an object described above, an organic EL device manufacturing method according to one aspect of the present disclosure is a method of manufacturing an organic EL device including: a pair of electrodes; a light-emitting layer between the electrodes; and a carrier transport layer between one of the electrodes and the light-emitting layer. The organic EL device manufacturing method includes: adding, to the carrier transport layer, an ion derived from a material different from a constituent material included in the carrier transport layer, where the ion has a polarity same as the polarity of a carrier to be transported in the carrier transport layer.

To achieve an object described above, an organic EL device characterization method according to one aspect of the present disclosure is a method of evaluating the property of an organic EL device including: a pair of electrodes; a light-emitting layer between the electrodes; and a carrier transport layer between one of the electrodes and the light-emitting layer. The organic EL device characterization method includes performing displacement current measurement. In the displacement current measurement, in a measuring element including: a constituent material included in the carrier transport layer; an insulating layer disposed only on one side of sides of the constituent material in a thickness direction of the constituent material; and a pair of electrodes sandwiching the constituent material and the insulating layer in the thickness direction, (i) a voltage which periodically varies and whose polarity is periodically inverted is applied between the electrodes, and (ii) an ion included in the constituent material is measured based on a current that flows through the measuring element by the application of the voltage. The ion is derived from a material different from the constituent material and has a polarity same as the polarity of a carrier to be transported in the carrier transport layer.

### Advantageous Effects of Invention

The organic EL device and the like according to the present disclosure advantageously facilitate the improvement of characteristics including luminous efficiency.

### BRIEF DESCRIPTION OF DRAWINGS

FIG. 1 is a schematic diagram illustrating the structure of an organic EL device according to an embodiment.

FIG. 2 is a schematic diagram illustrating the configuration of a measurement system according to the embodiment.

FIG. 3 is a schematic diagram illustrating a measuring element according to the embodiment.

FIG. 4 is a flowchart illustrating an example of displacement current measurement according to the embodiment.

FIG. 5 is a diagram illustrating an example of measurement results for a target material to be measured, before and after being purified by sublimation, obtained by the displacement current measurement according to the embodiment.

FIG. 6 is a diagram illustrating a comparative example of measurement results for the target material to be measured, before and after being purified by sublimation, obtained by the displacement current measurement according to the embodiment.

FIG. 7 is a flowchart illustrating an example of an organic EL device manufacturing method according to the embodiment.

FIG. 8 is a diagram illustrating measurement results of drive voltage among initial properties of the organic EL device according to the embodiment.

FIG. 9 is a diagram illustrating measurement results of emission spectrum among the initial properties of the organic EL device according to the embodiment.

FIG. 10 is a diagram illustrating measurement results of current efficiency among the initial properties of the organic EL device according to the embodiment.

FIG. 11 is a diagram illustrating measurement results of external quantum efficiency among the initial properties of the organic EL device according to the embodiment.

FIG. 12 is a diagram illustrating measurement results of drive voltage in deterioration analysis of the organic EL device according to the embodiment.

FIG. 13 is a diagram illustrating measurement results of luminous intensity in the deterioration analysis of the organic EL device according to the embodiment.

FIG. 14 is a diagram illustrating measurement results of current efficiency in the deterioration analysis of the organic EL device according to the embodiment.

FIG. 15 is a diagram illustrating measurement results of luminous efficiency in the deterioration analysis of the organic EL device according to the embodiment.

FIG. 16 is an enlarged diagram of measurement results for 0 to 100 hours of operation time of the organic EL device in FIG. 15.

FIG. 17 is an enlarged diagram of measurement results for 1500 to 2000 hours of operation time of the organic EL device in FIG. 15.

### DESCRIPTION OF EMBODIMENTS

An embodiment will be specifically described below with reference to the drawings.

The embodiment to be described below illustrates general and specific examples. Numerical values, shapes, materials, constituent elements, the arrangements of and connections between the constituent elements, etc., illustrated in the following embodiment are merely exemplary and not intended to limit the claims. Of the constituent elements in the following embodiment, those not set forth in the independent claims indicating the highest-level concepts will be described as optional constituent elements. The drawings are not necessarily exact illustrations. Throughout the drawings, substantially like elements are given like symbols, and repeated description of such elements will be omitted or simplified.

### 1. Organic EL Device

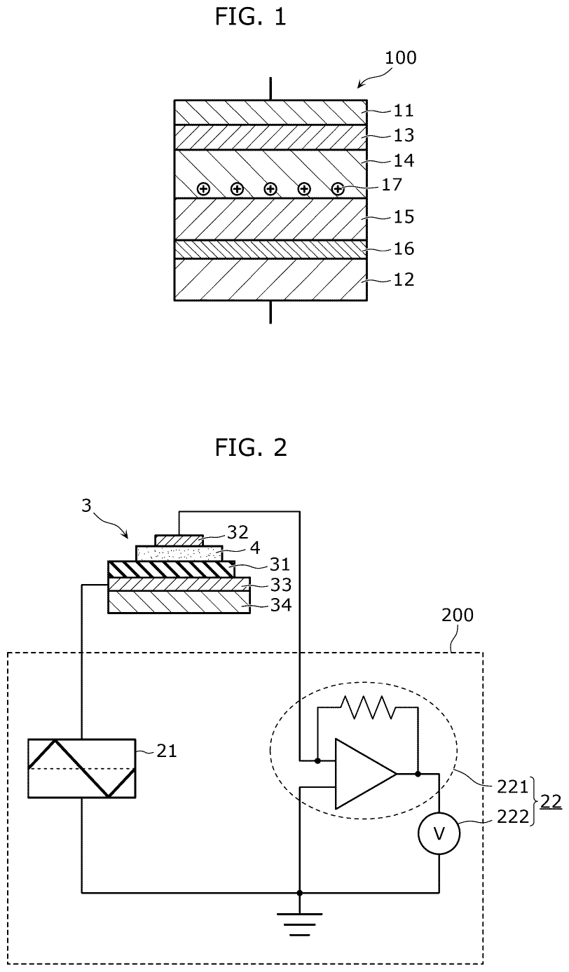

FIG. 1 is a schematic diagram illustrating the structure of organic EL device 100 according to an embodiment. In the embodiment, organic EL device 100 is an organic light-emitting diode. In the embodiment, organic EL device 100 has a configuration in which holes as carriers are excessive.

As illustrated in FIG. 1, organic EL device 100 includes a pair of electrodes 11 and 12; hole injection layer 13; hole transport layer 14; light-emitting layer 15 including an electron transport layer; and electron injection layer 16. In the embodiment, hole transport layer 14 and the electron transport layer correspond to a first carrier transport layer and a second carrier transport layer. In the embodiment, the first carrier transport layer is hole transport layer 14, and the second carrier transport layer is the electron transport layer.

First electrode 11, which is one of the pair of electrodes 11 and 12, is an anode formed with indium tin oxide (ITO) as a constituent material. First electrode 11 has a thickness of several tens of nanometers to one hundred and several tens of nanometers, for example.

Second electrode 12, which is the other one of the pair of electrodes 11 and 12, is a cathode formed with aluminum (Al) as a constituent material. Second electrode 12 has a thickness of several tens of nanometers to one hundred and several tens of nanometers, for example.

Hole injection layer 13, which is disposed on one face (the bottom face in FIG. 1) of first electrode 11 orthogonal to the thickness direction of first electrode 11, is formed with molybdenum (VI) oxide (MoO3) as a constituent material. Hole injection layer 13 has a thickness of a few tenths of nanometers, for example.

Hole transport layer 14, which is disposed on one face (the bottom face in FIG. 1) of hole injection layer 13 orthogonal to the thickness direction, is formed with α-NPD (N,N′-bis(1-naphthyl)-N,N′-diphenyl-1,1′-biphenyl-4,4′-diamine) as a constituent material. In other words, α-NPD is a constituent material of hole transport layer 14 (i.e., the first carrier transport layer). Hole transport layer 14 has a thickness of several tens of nanometers, for example. In other words, hole transport layer 14 (a carrier transport layer) is disposed between one of the pair of electrodes 11 and 12 (first electrode 11) and light-emitting layer 15.

In the embodiment, hole transport layer 14 contains cations 17 as impurities (or an additive). Cations 17 are ions derived not from α-NPD but from a material different from α-NPD. Typically, acceptors are added to hole transport layer 14 to withdraw electrons, so that α-NPD enters a cationic state and the acceptors become anions. In the embodiment, cations 17 in hole transport layer 14 are not α-NPD in the cationic state but ions contained as impurities in α-NPD. Unlike α-NPD in the cationic state, cations 17 are movable ions that can move in response to the application of voltage between the pair of electrodes 11 and 12.

Thus, in the embodiment, the first carrier transport layer (here, hole transport layer 14) contains ions (here, cations 17) that are derived from a material different from a constituent material (here, α-NPD) of the first carrier transport layer and that have the same polarity as carriers (here, holes) to be transported in the first carrier transport layer. Whether the first carrier transport layer contains the above ions can be determined by displacement current measurement, which will be described in detail below in [2. Displacement current measurement].

Light-emitting layer 15 including the electron transport layer, which is disposed on one face (the bottom face in FIG. 1) of hole transport layer 14 orthogonal to the thickness direction, is formed with Alq3 (tris(8-hydroxyquinolinato)aluminium) as a constituent material. Light-emitting layer 15 including the electron transport layer has a thickness of several tens of nanometers, for example. In other words, light-emitting layer 15 is disposed between the pair of electrodes 11 and 12.

Electron injection layer 16, which is disposed between one face (the bottom face in FIG. 1) of light-emitting layer 15 including the electron transport layer, orthogonal to the thickness direction, and one face (the top face in FIG. 1) of second electrode 12 orthogonal to the thickness direction, is formed with lithium fluoride (LiF) as a constituent material. Electron injection layer 16 has a thickness of a few tenths of nanometers, for example.

### 2. Displacement Current Measurement

Displacement current measurement for determining whether the first carrier transport layer (here, hole transport layer 14) contains the ions (here, cations 17) will be described below. The displacement current measurement is performed using measurement system 200 illustrated in FIG. 2.

FIG. 2 is a schematic diagram illustrating the configuration of measurement system 200 according to the embodiment. Measurement system 200 according to the embodiment determines the polarity of ions (impurity ions) in target material to be measured 4, which is a solid object. Specifically, in measurement system 200 according to the embodiment, measuring element 3 includes target material to be measured 4, which is a thin film. Voltage is applied to a pair of electrodes 32 and 33 (to be described below) of measuring element 3 to measure impurity ions in target material to be measured 4.

As illustrated in FIG. 2, measurement system 200 includes voltage applier 21 and measurer 22.

Voltage applier 21 is connected between the pair of electrodes 32 and 33 of measuring element 3 and applies, between the pair of electrodes 32 and 33, periodically varying voltage whose polarity is periodically inverted. In the embodiment, voltage applier 21 is a function generator that generates triangular wave voltage as the periodically varying voltage whose polarity is periodically inverted, and applies the generated triangular wave voltage between the pair of electrodes 32 and 33. As an example, the triangular wave voltage has a frequency of 0.001 Hz and an amplitude of ±10 V.

Note that the above frequency and amplitude of the triangular wave voltage are merely exemplary and not limiting. However, the triangular wave voltage preferably has a relatively low frequency. This is because high-frequency triangular wave voltage would invert its polarity before the ions in target material to be measured 4 reach insulating layer 31 (to be described below), preventing the measurement of current attributed to the ions to be measured.

Measurer 22 measures physical properties of target material to be measured 4 based on current that flows through measuring element 3 due to the application of the voltage by voltage applier 21. In the embodiment, the physical properties of target material to be measured 4 include at least the polarity of the ions in target material to be measured 4. In the embodiment, the physical properties of target material to be measured 4 also include the ionic quantity of the ions in target material to be measured 4.

In the embodiment, measurer 22 includes I-V converter 221 and voltmeter 222. I-V converter 221, which is connected in series with the pair of electrodes 32 and 33 of measuring element 3, converts the current flowing through measuring element 3 into voltage. Voltmeter 222 measures the voltage resulting from the conversion by I-V converter 221. Thus, measurer 22 measures the current flowing through measuring element 3, using I-V converter 221 that converts the current into voltage and voltmeter 222 that measures the voltage.

By measuring the current flowing through measuring element 3, measurer 22 determines the polarity and ionic quantity of the ions in target material to be measured 4, as will be described in detail below.

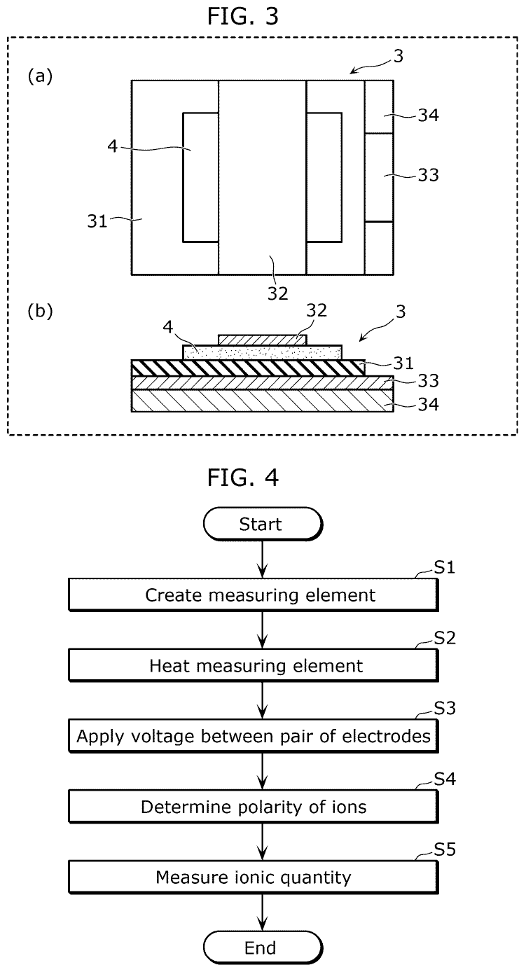

FIG. 3 is a schematic diagram illustrating measuring element 3 according to the embodiment. In FIG. 3, (a) is a plan view of measuring element 3, and (b) is a cross-sectional view of measuring element 3. As illustrated in FIG. 3, measuring element 3 includes insulating layer 31, the pair of electrodes 32 and 33, glass substrate 34, and target material to be measured 4. In the embodiment, measuring element 3 is square-shaped with several centimeters per side in plan view.

Insulating layer 31 is a silicon nitride (SiN) insulating film. Note that insulating layer 31 may be made of any material; for example, insulating layer 31 may be a polyimide insulating film. Insulating layer 31 is formed on one face (here, the top face) of electrode 33, which is one (here, the lower one) of the pair of electrodes 32 and 33. Target material to be measured 4 is disposed on the face (i.e., the top face) of insulating layer 31 closer to electrode 32, which is the other (here, the upper) electrode.

Electrode 32, which is one (here, the upper one) of the pair of electrodes 32 and 33, is an aluminum (Al) electrode. Electrode 33, which is the other one (here, the lower one) of the pair of electrodes 32 and 33, is a transparent ITO electrode. Note that the pair of electrodes 32 and 33 may be made of any material.

Electrode 32, which is one (here, the upper one) of the pair of electrodes 32 and 33, is disposed on one face (here, the top face) of target material to be measured 4. Electrode 33, which is the other one (here, the lower one) of the pair of electrodes 32 and 33, is formed on one face (here, the top face) of glass substrate 34. Part of electrode 32 and electrode 33 of the pair of electrodes 32 and 33 is exposed outside to allow voltage applier 21 and measurer 22 to be electrically connected to the exposed part via electric wires.

As above, insulating layer 31 is disposed only on one (here, the lower one) of the opposite sides of target material to be measured 4 in the thickness direction (here, the top-down direction) of target material to be measured 4. The pair of electrodes 32 and 33 are disposed to sandwich target material to be measured 4 and insulating layer 31 in the thickness direction. Thus, of the opposite faces of target material to be measured 4 orthogonal to the thickness direction, one face (here, the bottom face) is in contact with insulating layer 31, whereas the other face (here, the top face) is in contact with electrode 32 with no intervening insulating layer.

Note that, in the embodiment, the dimensions of electrode 32, target material to be measured 4, insulating layer 31, and electrode 33 are larger in this order along the width (here, the right-left direction) of measuring element 3. However, this is not intended to limit the widths of these components. Further, in the embodiment, the dimension of target material to be measured 4 is smaller than the dimensions of electrode 32 and insulating layer 31 along the depth (here, the direction orthogonal to the drawing plane in (b)) of measuring element 3. However, this is not intended to limit the depths of these components.

In the embodiment, target material to be measured 4 is a constituent material (here, α-NPD) of the first carrier transport layer (here, hole transport layer 14) in organic EL device 100. Note that target material to be measured 4 may be a constituent material of the second carrier transport layer (here, the electron transport layer) in organic EL device 100.

In the embodiment, target material to be measured 4 is a solid object, specifically a thin film. Target material to be measured 4 in the embodiment has a thickness of several tens of nanometers, although it may have a thickness of several hundreds of nanometers. Note that target material to be measured 4 may be any solid object not limited to a thin film.

Operations of measurement system 200, i.e., the displacement current measurement, according to the embodiment will be described below with reference to FIG. 4. FIG. 4 is a flowchart illustrating an example of the displacement current measurement according to the embodiment.

First, measuring element 3 is created (step S1). Specifically, an element is created that includes electrode 33, insulating layer 31, a thin film of target material to be measured 4, and electrode 32, layered in this order on one face (here, the top face) of glass substrate 34.

Measuring element 3 is heated (step S2). Here, measuring element 3 is heated until the ambient temperature of measuring element 3 reaches approximately 40 to 80 degrees Celsius. While measuring element 3 is being heated, or while measuring element 3 is kept in a high-temperature environment, voltage applier 21 applies voltage (here, triangular wave voltage) between the pair of electrodes 32 and 33 of measuring element 3 (step S3). That is, in the embodiment, the voltage applied between the pair of electrodes 32 and 33 at step S3 is applied at a temperature higher than room temperature (here, at approximately 40 to 80 degrees Celsius).

Heating measuring element 3 as above is expected to increase the mobility of the ions in target material to be measured 4. Further, compared to unheated measuring element 3, the accuracy of measuring the ionic quantity can be improved at step S5 (to be described below) of measuring the ionic quantity of the ions in target material to be measured 4.

Measurer 22 measures current flowing between the pair of electrodes 32 and 33 of measuring element 3 and, based on the measured current, determines the polarity of the ions in target material to be measured 4 (step S4). Further, based on the measured current, measurer 22 measures the ionic quantity of the ions in target material to be measured 4 (step S5).

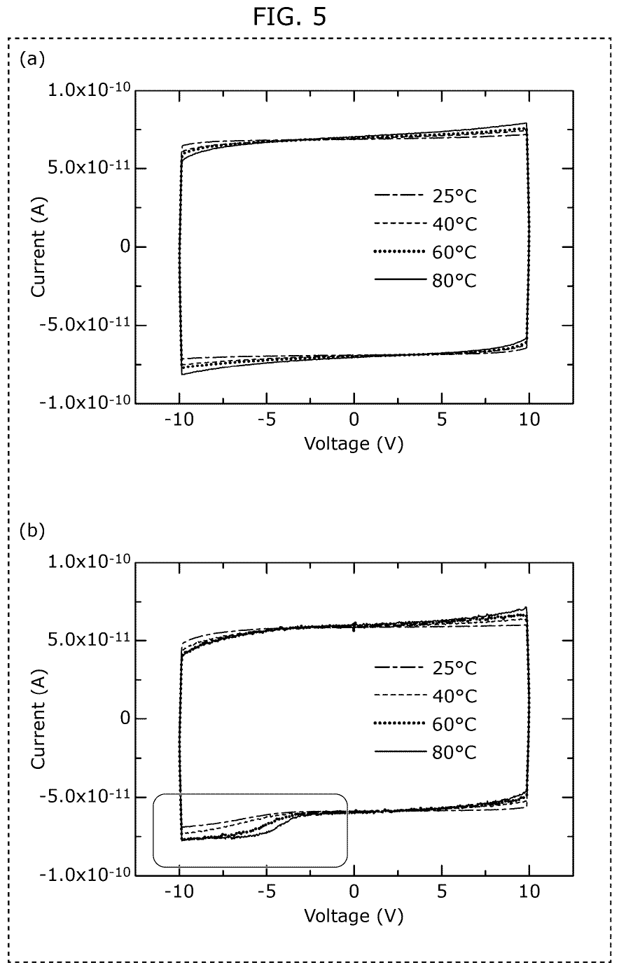

Now, specific examples of determining the polarity and ionic quantity of the ions in target material to be measured 4 will be described with reference to FIG. 5. FIG. 5 is a diagram illustrating an example of measurement results for target material to be measured 4 before and after being purified by sublimation, obtained by the displacement current measurement according to the embodiment. In FIG. 5, (a) is an illustration of measurement results for target material to be measured 4 purified by sublimation, and (b) is an illustration of measurement results for unpurified target material to be measured 4. That is, (a) in FIG. 5 illustrates measurement results for target material to be measured 4 with impurities removed by sublimation, whereas (b) in FIG. 5 illustrates measurement results for target material to be measured 4 with impurities unremoved.

For the measurement results shown in FIG. 5, the ordinate indicates the current (in “A”) flowing between the pair of electrodes 32 and 33 of measuring element 3, and the abscissa indicates the voltage (in “V”) applied between the pair of electrodes 32 and 33. In FIG. 5, dashed and single-dotted lines indicate measurement results at room temperature (here, 25 degrees Celsius), dashed lines indicate measurement results for measuring element 3 heated to 40 degrees Celsius, dotted lines indicate measurement results for measuring element 3 heated to 60 degrees Celsius, and solid lines indicate measurement results for measuring element 3 heated to 80 degrees Celsius.

As illustrated in (a) in FIG. 5, the measurement results for target material to be measured 4 purified by sublimation show peaks that project slightly from the parallelogram-shaped graph in both the first and third quadrants, but there are no significant differences among the peaks. In contrast, as illustrated in (b) in FIG. 5, the measurement results for unpurified target material to be measured 4 show noticeable peaks that project from the parallelogram-shaped graph, especially in the third quadrant (see inside the rectangular box in (b) in FIG. 5). The peaks are more noticeable at higher temperatures of measuring element 3.

Thus, calculating the area of the regions including the peaks allows measuring the ionic quantity of the ions (impurity ions) in target material to be measured 4. The peaks appear noticeably in the third quadrant, i.e., the period in which the voltage applied to measuring element 3 switches from positive to negative. That is, the peaks are observed due to the ions moving to a surface of insulating layer 31 disposed on electrode 33, which acts as the negative electrode in this period, of the pair of electrodes 32 and 33. It can therefore be determined that the ions (impurity ions) in target material to be measured 4 (here, α-NPD) are cations.

The ions measured by this displacement current measurement are movable ions that move in response to the application of voltage between the pair of electrodes 32 and 33. That is, this displacement current measurement can measure movable ions (here, cations) contained as impurities in target material to be measured 4, rather than measuring target material to be measured 4 in the cationic state.

No peaks appear in the first quadrant, because no insulating layer is disposed on electrode 32. That is, in the first quadrant, i.e., the period in which the voltage applied to measuring element 3 switches from negative to positive, electrode 32 of the pair of electrodes 32 and 33 acts as the negative electrode. However, with no insulating layer disposed on electrode 32, no ions in target material to be measured 4 are detected, resulting in no peaks observed in the first quadrant.

As mentioned above, the above peaks are more noticeable at higher temperatures of measuring element 3. This means that increasing the temperature of measuring element 3 facilitates measuring the ionic quantity of the ions in target material to be measured 4.

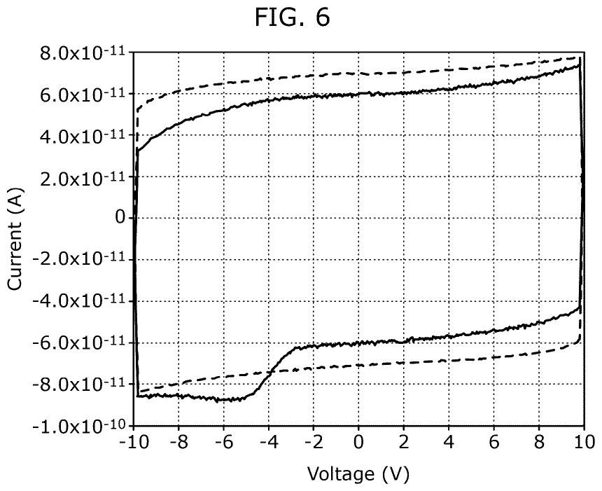

FIG. 6 is a diagram illustrating a comparative example of measurement results for target material to be measured 4 before and after being purified by sublimation, obtained by the displacement current measurement according to the embodiment. For the measurement results shown in FIG. 6, the ordinate indicates the current (in “A”) flowing between the pair of electrodes 32 and 33 of measuring element 3, and the abscissa indicates the voltage (in “V”) applied between the pair of electrodes 32 and 33. In FIG. 6, dashed lines indicate measurement results for unpurified target material to be measured 4, and solid lines indicate measurement results for target material to be measured 4 purified by sublimation. The measurement results in FIG. 6 are those observed for measuring element 3 heated to 80 degrees Celsius. As illustrated in FIG. 6, with the displacement current measurement according to the embodiment, peaks attributed to the ions (impurity ions) in target material to be measured 4 can be observed in the first or third quadrant (here, the third quadrant).

Now, if the ions (impurity ions) in target material to be measured 4 were anions, a noticeable peak projecting from the parallelogram-shaped graph would appear in the first quadrant, rather than the third quadrant. That is, in the period in which the voltage applied to measuring element 3 switches from negative to positive, electrode 33 of the pair of electrodes 32 and 33 acts as the negative electrode. A peak would therefore be observed in this period due to the ions moving to a surface of insulating layer 31 disposed on electrode 33. It would thus be determined that the ions (impurity ions) in target material to be measured 4 are anions.

### 3. Organic EL Device Manufacturing Method

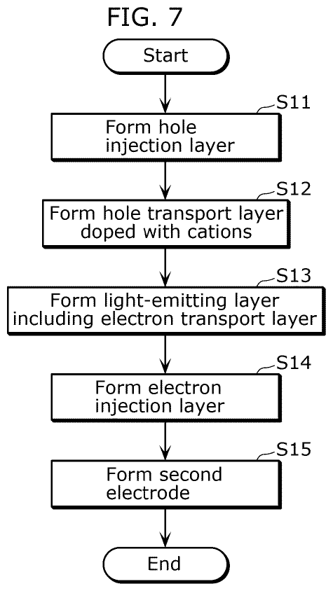

A method of manufacturing organic EL device 100 according to the embodiment will be described below with reference to FIG. 7. FIG. 7 is a flowchart illustrating an example of a method of manufacturing organic EL device 100 according to the embodiment. The description here illustrates a method of manufacturing organic EL device 100 in which the first carrier transport layer is hole transport layer 14. Although vacuum deposition is used here to manufacture organic EL device 100, other techniques may be used to manufacture organic EL device 100.

First, a glass substrate having first electrode 11, which is a prepatterned transparent electrode, is prepared, and hole injection layer 13 is formed on one face of first electrode 11 orthogonal to the thickness direction of first electrode 11 (step S11). Hole transport layer 14 is doped with cations 17 and formed on one face of hole injection layer 13 orthogonal to the thickness direction and opposite to first electrode 11 (step S12).

Note that, if a constituent material (here, α-NPD) of hole transport layer 14 is doped with cations 17 in advance, the step of doping with cations 17 may be skipped. Similarly, if the constituent material of hole transport layer 14 already contains cations 17 as impurity ions as determined by the displacement current measurement, the step of doping with cations 17 may be skipped.

Light-emitting layer 15 including an electron transport layer is formed on one face of hole transport layer 14 orthogonal to the thickness direction and opposite to first electrode 11 (step S13). Step S15 may be divided into the step of forming the electron transport layer and the step of forming light-emitting layer 15. Electron injection layer 16 is formed on one face of light-emitting layer 15 including the electron transport layer, orthogonal to the thickness direction and opposite to first electrode 11 (step S14). Second electrode 12 is formed on one face of electron injection layer 16 orthogonal to the thickness direction and opposite to first electrode 11 (step S15). Through the above sequence of steps, organic EL device 100 is manufactured.

### 4. Properties of Organic EL Device

Properties of organic EL device 100 according to the embodiment will be described below with comparison to an organic EL device in a comparative example. The organic EL device in the comparative example is different from organic EL device 100 according to the embodiment in that the organic EL device in the comparative example includes a hole transport layer purified by sublimation, i.e., a hole transport layer containing no cations.

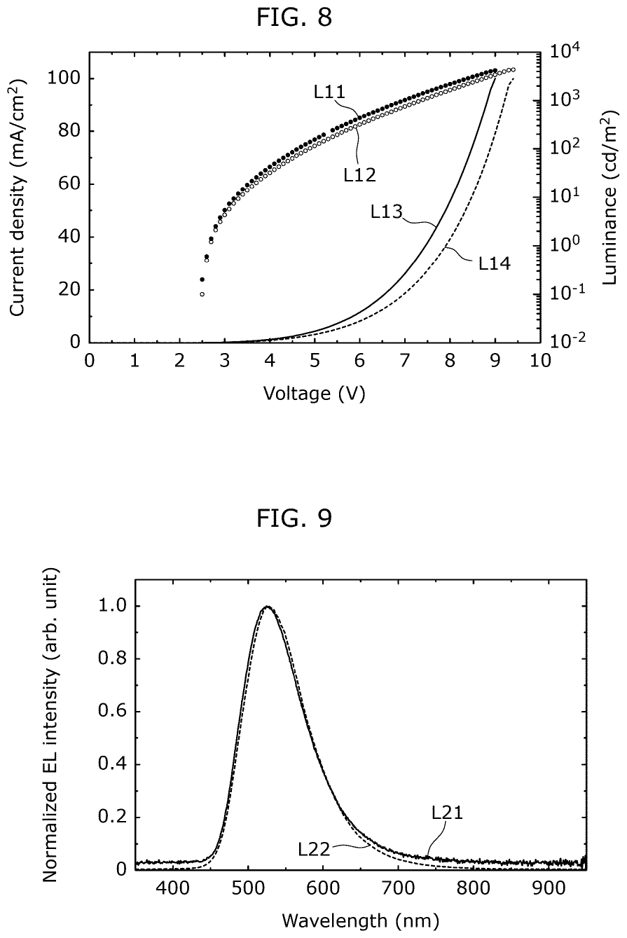

First, results of comparing initial properties of organic EL device 100 according to the embodiment with those of the organic EL device in the comparative example will be described. FIG. 8 is a diagram illustrating measurement results of drive voltage among the initial properties of organic EL device 100 according to the embodiment. For the measurement results shown in FIG. 8, the left ordinate indicates the current density (in “mA/cm²”) of the organic EL devices, the right ordinate indicates the luminance (in “cd/m²”) of the organic EL devices, and the abscissa indicates the drive voltage (in “V”) of the organic EL devices. In FIG. 8, curved line L11 indicates measurement results of the luminance of the organic EL device in the comparative example, and curved line L12 indicates measurement results of the luminance of organic EL device 100 according to the embodiment; curved line L13 indicates measurement results of the current density of the organic EL device in the comparative example, and curved line L14 indicates measurement results of the current density of organic EL device 100 according to the embodiment.

As illustrated in FIG. 8, the results show that, to achieve certain current density or luminance, organic EL device 100 according to the embodiment requires higher drive voltage than the organic EL device in the comparative example. This leads to a finding that the presence of ions (impurity ions, here, cations 17) in the first carrier transport layer (here, hole transport layer 14) slightly increases the drive voltage of the organic EL device.

FIG. 9 is a diagram illustrating measurement results of emission spectrum among the initial properties of organic EL device 100 according to the embodiment. For the measurement results shown in FIG. 9, the ordinate indicates the normalized intensity (in “arbitrary unit (arb. unit)”) of light emitted by the organic EL devices, and the abscissa indicates the wavelength (in “nm”) of the light emitted by the organic EL devices. In FIG. 9, curved line L21 indicates measurement results for the organic EL device in the comparative example, and curved line L22 indicates measurement results for organic EL device 100 according to the embodiment.

As illustrated in FIG. 9, the results show no significant differences in emission spectrum between organic EL device 100 according to the embodiment and the organic EL device in the comparative example. This leads to a finding that the presence of ions (impurity ions, here, cations 17) in the first carrier transport layer (here, hole transport layer 14) has little influence on the emission spectrum of the organic EL device.

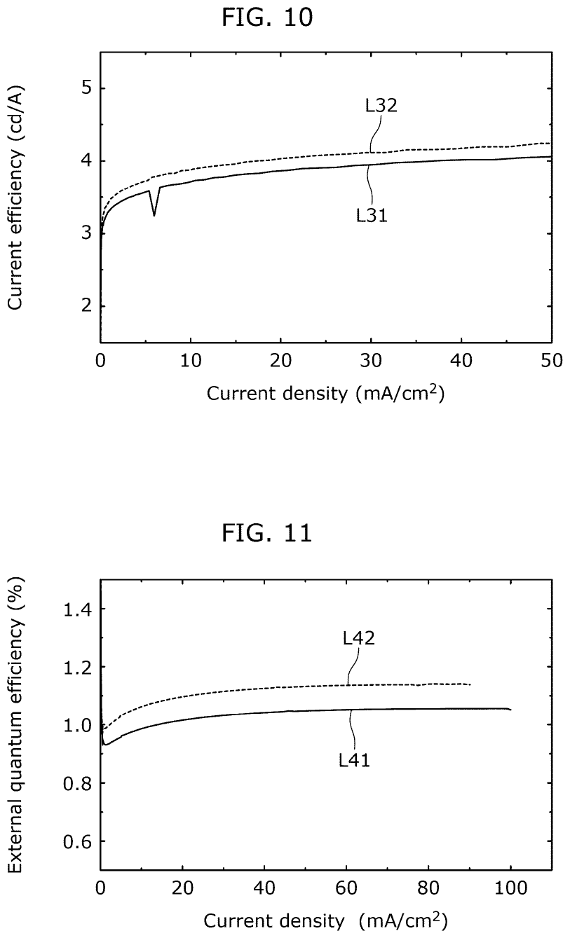

FIG. 10 is a diagram illustrating measurement results of current efficiency among the initial properties of organic EL device 100 according to the embodiment. For the measurement results shown in FIG. 10, the ordinate indicates the current efficiency (in “cd/A”) of the organic EL devices, and the abscissa indicates the current density (in “mA/cm²”) of the organic EL devices. In FIG. 10, curved line L31 indicates measurement results for the organic EL device in the comparative example, and curved line L32 indicates measurement results for organic EL device 100 according to the embodiment.

As illustrated in FIG. 10, the results show that organic EL device 100 according to the embodiment is higher in current efficiency than the organic EL device in the comparative example. This leads to a finding that the presence of ions (impurity ions, here, cations 17) in the first carrier transport layer (here, hole transport layer 14) increases the current efficiency of the organic EL device.

FIG. 11 is a diagram illustrating measurement results of external quantum efficiency among the initial properties of organic EL device 100 according to the embodiment. For the measurement results shown in FIG. 11, the ordinate indicates the external quantum efficiency (in “%”) of the organic EL devices, and the abscissa indicates the current density (in “mA/cm²”) of the organic EL devices. In FIG. 11, curved line L41 indicates measurement results for the organic EL device in the comparative example, and curved line L42 indicates measurement results for organic EL device 100 according to the embodiment.

As illustrated in FIG. 11, the results show that organic EL device 100 according to the embodiment is higher in external quantum efficiency than the organic EL device in the comparative example. This leads to a finding that the presence of ions (impurity ions, here cations 17) in the first carrier transport layer (here, hole transport layer 14) increases the external quantum efficiency of the organic EL device.

The above amounts to a finding that the presence of ions (impurity ions, here, cations 17) in the first carrier transport layer (here, hole transport layer 14) increases the current efficiency and the external quantum efficiency (i.e., the light-emitting efficiency) of the organic EL device, although slightly increasing the drive voltage.

Next, results of comparing the lifetime of organic EL device 100 according to the embodiment with the lifetime of the organic EL device in the comparative example will be described. For both organic EL device 100 according to the embodiment and the organic EL device in the comparative example, changes over time were measured in voltage, luminous intensity, current efficiency, and luminous efficiency, at room temperature while current was applied at a constant current density of 50 mA/cm².

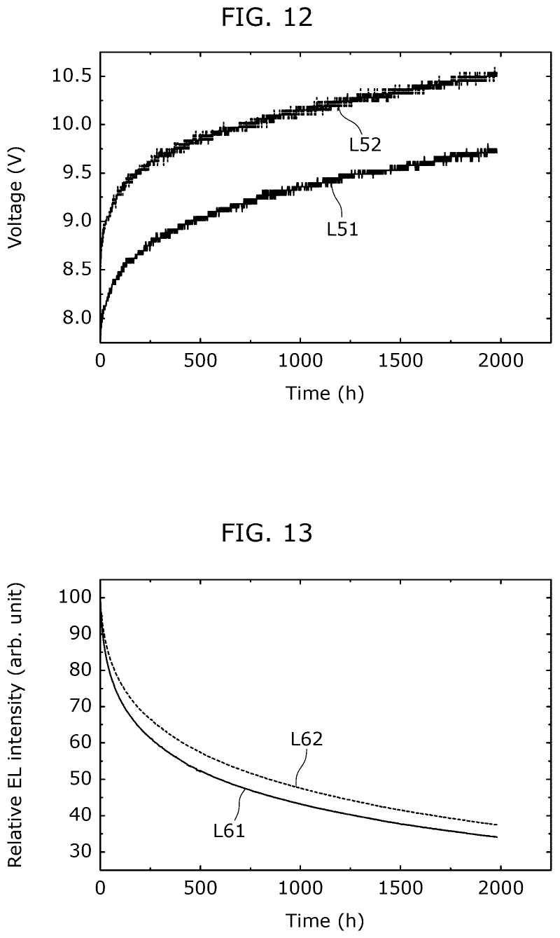

FIG. 12 is a diagram illustrating measurement results of drive voltage in deterioration analysis of organic EL device 100 according to the embodiment. For the measurement results shown in FIG. 12, the ordinate indicates the drive voltage (in “V”) of the organic EL devices, and the abscissa indicates the operation time (in “h”) of the organic EL devices. In FIG. 12, curved line L51 indicates measurement results for the organic EL device in the comparative example, and curved line L52 indicates measurement results for organic EL device 100 according to the embodiment.

As illustrated in FIG. 12, the results show that, throughout 2000 hours of operation time, almost the same tendency in drive voltage increase is observed for both the organic EL device in the comparative example and organic EL device 100 according to the embodiment. This leads to a finding that the presence of ions (impurity ions, here, cations 17) in the first carrier transport layer (here, hole transport layer 14) has little time-varying influence on the drive voltage of the organic EL device.

FIG. 13 is a diagram illustrating measurement results of luminous intensity in the deterioration analysis of organic EL device 100 according to the embodiment. For the measurement results shown in FIG. 13, the ordinate indicates the intensity (in “arb. unit”) of the organic EL devices relative to the intensity at initial operation (0 hours of operation time) regarded as 100, and the abscissa indicates the operation time (in “h”) of the organic EL devices. In FIG. 13, curved line L61 indicates measurement results for the organic EL device in the comparative example, and curved line L62 indicates measurement results for organic EL device 100 according to the embodiment.

As illustrated in FIG. 13, the results show that, throughout 2000 hours of operation time, organic EL device 100 according to the embodiment decreases in intensity at a lower rate than the organic EL device in the comparative example. This leads to a finding that the presence of ions (impurity ions, here, cations 17) in the first carrier transport layer (here, hole transport layer 14) makes the intensity of the organic EL device less likely to decrease over the operation time.

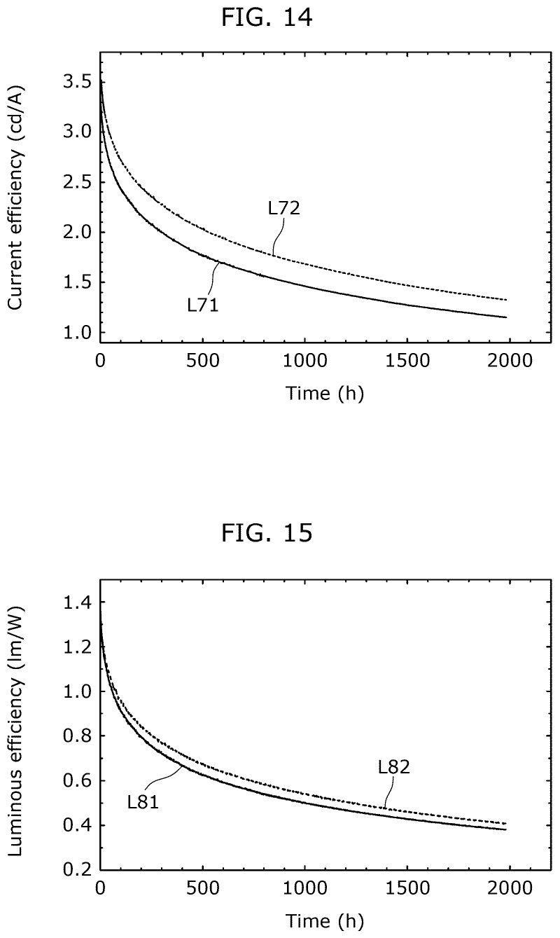

FIG. 14 is a diagram illustrating measurement results of current efficiency in the deterioration analysis of organic EL device 100 according to the embodiment. For the measurement results shown in FIG. 14, the ordinate indicates the current efficiency (in “cd/A”) of the organic EL devices, and the abscissa indicates the operation time (in “h”) of the organic EL devices. In FIG. 14, curved line L71 indicates measurement results for the organic EL device in the comparative example, and curved line L72 indicates measurement results for organic EL device 100 according to the embodiment.

As illustrated in FIG. 14, the results show that, throughout 2000 hours of operation time, organic EL device 100 according to the embodiment decreases in current efficiency at a lower rate than the organic EL device in the comparative example. This leads to a finding that the presence of ions (impurity ions, here, cations 17) in the first carrier transport layer (here, hole transport layer 14) makes the current efficiency of the organic EL device less likely to decrease over the operation time.

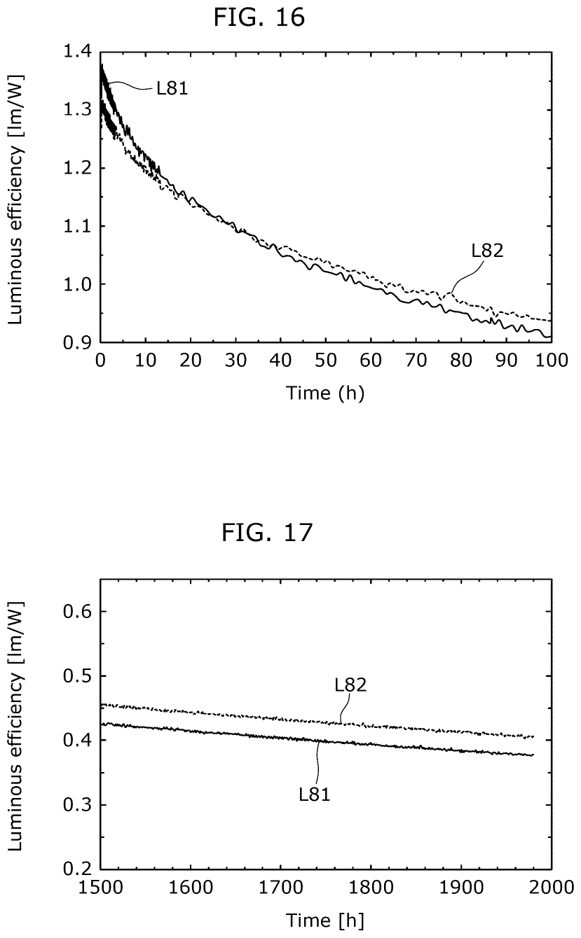

FIG. 15 is a diagram illustrating measurement results of luminous efficiency in the deterioration analysis of organic EL device 100 according to the embodiment. For the measurement results shown in FIG. 15, the ordinate indicates the luminous efficiency (in “Im/W”) of the organic EL devices, and the abscissa indicates the operation time (in “h”) of the organic EL devices. FIG. 16 is an enlarged diagram of the measurement results for 0 to 100 hours of operation time of the organic EL devices in FIG. 15, and FIG. 17 is an enlarged diagram of the measurement results for 1500 to 2000 hours of operation time of the organic EL devices in FIG. 15. In each of FIGS. 15 to 17, curved line L81 indicates measurement results for the organic EL device in the comparative example, and curved line L82 indicates measurement results for organic EL device 100 according to the embodiment.

As illustrated in FIGS. 15 and 16, until 25 hours of operation time, organic EL device 100 according to the embodiment is lower in luminous efficiency than the organic EL device in the comparative example. However, as illustrated in FIGS. 15 and 17, once the operation time exceeds 25 hours, organic EL device 100 according to the embodiment is higher in luminous efficiency than the organic EL device in the comparative example. This leads to a finding that the presence of ions (impurity ions, here, cations 17) in the first carrier transport layer (here, hole transport layer 14) makes the luminous efficiency of the organic EL device less likely to decrease over the operation time.

The above amounts to a finding that the presence of ions (impurity ions, here, cations 17) in the first carrier transport layer (here, hole transport layer 14) makes the intensity, current efficiency, and luminous efficiency of the organic EL device less likely to decrease over the operation time, that is, extends the lifetime of the organic EL device.

### 5. Advantages

Advantages of organic EL device 100 according to the embodiment will be described below in connection with findings that led to the creation of this disclosure. It has been known that ionic impurities in liquid crystal displays lower the functionality of the liquid crystal displays by causing reduced voltage retention, burn-in, reduced response time, or uneven luminance. However, it has been unknown whether ionic impurities in organic EL devices lower the functionality of the organic EL devices.

The inventor of the present application therefore made an organic EL device having a hole transport layer yet to be purified by sublimation, and an organic EL device having a hole transport layer purified by sublimation. The inventor of the present application compared properties of these organic EL devices to evaluate how the presence or absence of ionic impurities (here, cations) affects the properties of the organic EL devices.

Given the above finding that ionic impurities lower the functionality of liquid crystal displays, it would be expected that ionic impurities in organic EL devices also reduce the functionality of the organic EL devices. However, as described above in [4. Properties of organic EL device], the presence of ionic impurities (here, cations 17) in the first carrier transport layer (here, hole transport layer 14) actually improved the characteristics, including luminous efficiency, of organic EL device 100 and also extended the lifetime of organic EL device 100. This may be because the presence of cations 17 derived from a material different from a-NPD in hole transport layer 14 increased the drive voltage to prevent excessive holes.

Thus, organic EL device 100 according to the embodiment advantageously facilitates the improvement of characteristics including luminous efficiency, thanks to the carrier transport layer (here, hole transport layer 14) containing ions (here, cations 17) derived from a material different from a constituent material (here, α-NPD) of the carrier transport layer. Further, organic EL device 100 according to the embodiment advantageously has a longer lifetime thanks to the carrier transport layer containing the above ions.

### 6. Organic EL Device Characterization Method

A characterization method for organic EL device 100 according to the embodiment will be described below. As described above, properties of organic EL device 100 depend on whether the first carrier transport layer (here, hole transport layer 14) contains ions (impurity ions, here, cations 17). This means that determining whether the first carrier transport layer contains ions (impurity ions) using displacement current measurement allows evaluating properties of organic EL device 100 (in particular, characteristics including luminous efficiency, and lifetime).

Thus, it can be said that the characterization method for organic EL device 100 according to the embodiment includes performing displacement current measurement. The displacement current measurement is performed as in the process illustrated in FIG. 4 and therefore will not be described here.

### Variations

Although organic EL device 100, the manufacturing method of organic EL device 100, and the characterization method of organic EL device 100 according to the present disclosure have been described based on an embodiment, the present disclosure is not limited to the embodiment. Other embodiments obtained by various modifications to the embodiments which may be conceived by those skilled in the art, and embodiments achieved by combining elements and functions described in each of the embodiments are also included in the scope of the present disclosure so long as they do not depart from the essence of the present disclosure.

In the embodiment, the first carrier transport layer may be an electron transport layer and the ions (impurity ions) in the first carrier transport layer may be anions. For example, if the electron transport layer is formed with F8BT (poly(9,9-dioctylfluorene-alt-benzothiazole)) as a constituent material, the organic EL device has a configuration with excessive electrons. In this case, the impurities in the electron transport layer may be anions, which are ions derived not from F8BT but from a material different from F8BT. This will advantageously facilitate the improvement of characteristics, including luminous characteristics, of the organic EL device.

### Conclusion

As described above, organic EL device 100 according to a first aspect of the present disclosure includes: a pair of electrodes 11 and 12; light-emitting layer 15 between the pair of electrodes 11 and 12; and a carrier transport layer (a first carrier transport layer) between one (first electrode 11) of electrodes 11 and 12 and light-emitting layer 15. The carrier transport layer includes an ion derived from a material different from a constituent material included in the carrier transport layer, the ion having the same polarity as a carrier to be transported in the carrier transport layer.

This advantageously facilitates the improvement of characteristics, including luminous efficiency, of organic EL device 100.

Organic EL device 100 according to the second aspect of the present disclosure is organic EL device 100 in the first aspect, in which the carrier transport layer (the first carrier transport layer) is hole transport layer 14, and the ion is cation 17.

This advantageously facilitates the improvement of characteristics, including luminous efficiency, of organic EL device 100 having a configuration with excessive holes.

Organic EL device 100 according to a third aspect of the present disclosure is organic EL device 100 in the first or second aspect, in which the ion is measured by displacement current measurement. In the displacement current measurement, in measuring element 3 including: the constituent material (target material to be measured 4); insulating layer 31 disposed only on one side of sides of the constituent material in a thickness direction of the constituent material; and a pair of electrodes 32 and 33 sandwiching the constituent material and insulating layer 31 in the thickness direction, (i) a voltage which periodically varies and whose polarity is periodically inverted is applied between the pair of electrodes 32 and 33 (step S3), and (ii) the ion included in the constituent material is measured based on a current that flows through measuring element 3 due to the application of the voltage (steps S4 and S5).

Thus, the carrier transport layer includes the ion measurable by the displacement current measurement. This advantageously facilitates the improvement of characteristics, including luminous efficiency, of organic EL device 100.

A Method of manufacturing organic EL device 100 according to a fourth aspect of the present disclosure is a method of manufacturing an organic EL device including: a pair of electrodes 11 and 12; light-emitting layer 15 between the pair of electrodes 11 and 12; and a carrier transport layer (a first carrier transport layer) between one (first electrode 11) of electrodes 11 and 12 and light-emitting layer 15. The method of manufacturing organic EL device 100 includes adding, to the carrier transport layer, an ion derived from a material different from a constituent material included in the carrier transport layer, the ion having the same polarity as a carrier to be transported in the carrier transport layer.

This advantageously enables manufacturing organic EL device 100 that facilitates the improvement of characteristics including luminous efficiency.

The method of manufacturing organic EL device 100 according to a fifth aspect of the present disclosure is the method in the fourth aspect, in which the carrier transport layer (the first carrier transport layer) is hole transport layer 14, and the ion is cation 17.

This advantageously enables manufacturing organic EL device 100 that has a configuration with excessive holes and that facilitates the improvement of characteristics including luminous efficiency.

A characterization method for organic EL device 100 according to a sixth aspect of the present disclosure is a method of evaluating a property of organic EL device 100 including: a pair of electrodes 11 and 12; light-emitting layer 15 between the pair of electrodes 11 and 12; and a carrier transport layer (a first carrier transport layer) between one (first electrode 11) of electrodes 11 and 12 and light-emitting layer 15, the method including performing displacement current measurement. In the displacement current measurement, in measuring element 3 including: a constituent material (target material to be measured 4) included in the first carrier transport layer; insulating layer 31 disposed only on one side of sides of the constituent material in a thickness direction of the constituent material; and a pair of electrodes 32 and 33 sandwiching the constituent material and insulating layer 31 in the thickness direction, (i) a voltage which periodically varies and whose polarity is periodically inverted is applied between the electrodes (step S3), and (ii) an ion included in the constituent material is measured based on a current that flows through measuring element 3 due to the application of the voltage (steps S4 and S5). The ion is derived from a material different from the constituent material and has the same polarity as a carrier to be transported in the carrier transport layer.

Thus, the displacement current measurement is used to determine whether the carrier transport layer includes the ion. This advantageously facilitates the evaluation of characteristics, including luminous efficiency, of organic EL device 100.

The characterization method for organic EL device 100 according to a seventh aspect of the present disclosure is the method in the sixth aspect, in which the carrier transport layer (the first carrier transport layer) is hole transport layer 14, and the ion is cation 17.

Thus, the displacement current measurement is used to determine whether the carrier transport layer includes the ion. This advantageously facilitates the evaluation of characteristics, including luminous efficiency, of organic EL device 100 having a configuration with excessive holes.

### INDUSTRIAL APPLICABILITY

The present disclosure is applicable to organic EL devices, for example organic light-emitting diodes.

### REFERENCE SIGNS LIST

100 organic EL device
11 first electrode
12 second electrode
13 hole injection layer
14 hole transport layer
15 light-emitting layer
16 electron injection layer
17 cation
200 measurement system
21 voltage applier
22 measurer
221 I-V converter
222 voltmeter
3 measuring element
31 insulating layer
32,33 electrode
34 glass substrate
4 target material to be measured

1-5. (canceled)

6. An organic EL device characterization method of evaluating a property of an organic EL device including: a pair of electrodes; a light-emitting layer between the electrodes; and a carrier transport layer between one of the electrodes and the light-emitting layer, the organic EL device characterization method comprising:
performing displacement current measurement, wherein
in the displacement current measurement:
in an measuring element including: a constituent material included in the carrier transport layer; an insulating layer disposed only on one side of sides of the constituent material in a thickness direction of the constituent material; and a pair of electrodes sandwiching the constituent material and the insulating layer in the thickness direction, (i) a voltage which periodically varies and whose polarity is periodically inverted is applied between the electrodes, and (ii) an ion included in the constituent material is measured based on a current that flows through the measuring element by the application of the voltage, and
the ion is derived from a material different from the constituent material and has a polarity same as a polarity of a carrier to be transported in the carrier transport layer.

7. The organic EL device characterization method according to claim 6, wherein
the carrier transport layer is a hole transport layer, and
the ion is a cation.
